(19) United States
(12) Patent Application Publication
(10) Pub. No.: US 2008/0122067 A1
(43) Pub. Date: May 29, 2008

(54) HEAT SPREADER FOR AN ELECTRICAL DEVICE

(76) Inventor: CHUNG-CHENG WANG, Taichung (TW)

Correspondence Address: CHUNG-CHENG WANG, 10F, NO. 35 JIU LONG STREET BEITUN DISTRICT, TAICHUNG, 40645, omitted

(21) Appl. No.: 11/872,727

(22) Filed: Oct. 16, 2007

(30) Foreign Application Priority Data
Nov. 27, 2006 (TW) 95143670

(51) Int. Cl. H01L 23/34

(52) U.S. Cl. 257/706; 257/E23.08

(57) ABSTRACT

A heat spreader for electrical device is disclosed, a portion of said heat spreader is above and corresponding to a chip which is coupled with a base of electrical device. An embodiment for the heat spreader comprised of: a first portion, second portion, connecting portion, supporting portion and a side edge, said connecting portion is between said first portion and said second portion, said supporting portion coupled with the base of electrical device, said supporting portion is connected to the periphery of said first portion in order that said chip can be accommodated in said heat spreader; according to the heat spreader of the present invention, (i). Due to the side edge of said heat spreader can be protruded and exposed to the side wall of encapsulant, in this manner. Not only a larger chip can be placed in the heat spreader but the heat dissipation for said chip becomes more effective. (ii). More surfaces of said heat spreader enables to be encapsulated by an encapsulant, in this manner, the reliability of electrical device enables to be enhanced

### BACKGROUND OF THE INVENTION

1. Field of the Invention

The present invention relates to a heat spreader which is involved in an electrical device, more particularly, it relates that a heat spreader enables to be dissipating the heat of electrical device for enhancing the reliability of electrical device more effectively and be accommodating a larger chip therein for being more useful in the electronic industry.

2. Description of the Related Art

Nowadays, electrical devices are becoming more powerful than before, and usually, the more powerful the electrical device is, the hotter the electrical device is, due to a high-density chip is involved in the electrical device, the chip will generate heat while operating, nevertheless, it is not good for a chip to keep working in such a heating environment, due to it is easy to cause the chip to be not functional well, once the chip is not functional well, then the electrical device does not work well either, in this manner, the reliability of said electrical device becomes poor; meanwhile, users of electrical device are continually demanding better reliability of electrical devices, and inexpensive electrical devices. In this manner, manufacturers of electrical device research and develop the improved electrical devices for achieving the demands mentioned-above.

At first, referring to FIG. 13 which is a cross-sectional view shows a conventional electrical device 80 comprising: a base 30 serving as a substrate includes an upper surface 31, a corresponding lower surface 32, a plurality of conductive terminals 33 formed on the upper, lower surfaces 31,32 of said base 30 for electrical connection respectively, and a plurality of via 34 electrically connected the electrical terminals 33 on the upper surface 31 to the electrical terminals 33 on the lower surface 32 respectively; a chip 20 having a lower surface 22 and an upper surface 21 which is comprised of a plurality of bond pads 23 thereon, said chip 20 is mounted on the base 30 through its lower surface 22; a plurality of conductive means 60 serving as conductive wires are electrically connected said chip 20 to said base 30; a heat spreader 5 which is predetermined shape includes a first portion 1, a supporting portion 7 and a side edge 3, said first portion 1 is connected to said supporting portion 7, said first, supporting portion 1,7 having an upper surface 1a,7a and a corresponding lower surface 1b,7b respectively, said heat spreader 5 is mounted on the upper surface 31 of base 30 through the lower surface 7b of supporting portion 7, wherein the first portion 1 of heat spreader 5 is corresponding to the upper surface 21 of chip 20 and is above said chip 20; and an encapsulant 40 which is situated on the upper surface 31 of base 30 encapsulates said chip 20, conductive means(wires) 60, heat spreader 5 and said base 30 wherein the upper surface 1a of first portion 1 of said heat spreader 5 is exposed to the upper surface 41 of encapsulant 40;

According to the mentioned-above heat spreader 5 involved in the conventional electrical device 80, there are three disadvantages in said conventional electrical device 80, the details are as following:

(i). due to the main path “P1” of heat dissipation of chip 20 is from the chip 20 passing through the portion of encapsulant 40 which is between the first portion 1 of heat spreader 5 and the chip 20, the upper surface 1a of first portion 1 and then to the outside(atmosphere), wherein usually, there is a thickness “T” of the portion of encapsulant 40 which is between the first portion 1 of heat spreader 5 and the chip 20 is ≧0.4 m.m., and usually the encapsulant 40 is made of insulative material such as resin which is not a good material for transferring heat. For example: the encapsulant “GE-100” produced by NITTO DENKO, the thermal conductivity of said “GE-100” is 3.1 w/m-k only, in this manner, the thicker is the thickness “T” mentioned-above, the more difficult is the heat generated by the chip 20 transferred to the outside;

(ii). Due to both the Coefficient of Thermal Expansion of encapsulant 40 (such as the CTE of GE-100 is 15 ppm/° C.) and the CTE of heat spreader 5 which is made of metal (such as copper, the CTE of copper is 21 ppm/° C.) are different, in this manner, there will be a thermal stress occurring while the chip 20 is operating, and the thermal stress keeps on attacking the heat spreader 5 and the encapsulant 40 while said chip 20 is operating, as this result, it is easy to cause a peeling-off problem(i.e. there will be a gap “G” between the lower surface 1b of first portion 1 of said heat spreader 5 and the portion of encapsulant 40 which is contacted with said lower surface 1b of first portion 1 formed, once the gap “G” occurs, it is not easy for the heat generated by the chip 20 to be dissipated to the outside through the main path “P1” of heat dissipation, then it is easy to cause said chip 20 to become hotter, and the hotter the chip 20 is, the thermal stress attacks both the heat spreader 5 and the encapsulant 40 more seriously, then the gap “G” will become even bigger, and then it is more difficult for the heat generated by the chip 20 to be dissipated to the outside through the main path “P1”, and then it is easy to cause the chip 20 overheating, and eventually, said chip 20 will be damaged or not functional well (i.e. the conventional electrical device 80 will be damaged or not functional well) caused by the overheating mentioned above, thus the reliability of said conventional electrical device 80 becomes poor; and

(iii). Usually, the length that the lower surface 7b of supporting portion 7 of heat spreader 5 contacted with the upper surface 31 of base 30 is longer than 1 m.m., due to the side edge 3 of heat spreader 5 and the upper surface 7a of supporting portion 7 of heat spreader 5 are encapsulated by the encapsulant 40(i.e. both the side edge 3 of heat spreader 5 and the upper surface 7a of supporting portion 7 of heat spreader 5 are not exposed to the side wall 43 of encapsulant 40), then the distance “D” between the inside edge 7c of supporting portion 7 and the side edge 42 of encapsulant 40 is also longer than 1 m.m., moreover, the length “L” between both the supporting portion 7 and the corresponding supporting portion (7) can not be elongated, it is not good for said conventional electrical device 80 to be used in the electronic industry. Because both the chip 20 and conductive wires 60 are accommodated in the heat spreader 5, wherein the chip 20 needs to be electrically connected to the conductive terminal 33 formed on the upper surface 31 through the conductive wire 60(i.e. it is necessary that the area between said chip 20 and said inside edge 7c of supporting portion 7 of heat spreader 5 is big enough to be situated the conductive terminal 33 on the upper surface 31 of base 30). Should a larger chip be placed within the heat spreader 5, the larger chip will be near the inside edge 7c of supporting portion 7 very much, then the conductive terminal 33 can not be situated on the upper surface 31 of base 30 (due to the area between said larger chip and said inside edge 7c of supporting portion 7 is not big enough), and then said larger chip can not be electrically connected to the base 30 through the conductive wire 60. As it has already been mentioned above: “electrical devices are becoming more powerful than before”, wherein, the more powerful a chip is, the more the bond pads on chip is needed (i.e. the dimension for chip is needed to be larger in order to fit more bond pads disposed thereon), since it is not available for a lager chip to be used in said conventional electrical device 80, then it is restricted for said conventional electrical device 80 to be used, and then it is not good for said conventional electrical device 80 to be used in the electronic industry; in addition, the length “L2” of encapsulant 40 formed by the side edge 42 and the corresponding side edge(42) of said encapsulant 40 is longer than the length “L” mentioned-above, so that said heat spreader 5 enables to be encapsulated by said encapsulant 40.

### SUMMARY OF THE INVENTION

It is therefore an object of the invention to solve the mentioned-above problems, according to the heat spreader of the present invention, said heat spreader which is above and corresponding to a chip coupled with a base of an electrical device includes a first portion, a second portion, a connecting portion, a supporting portion and a side edge, said connecting portion is between said first portion and said second portion, said heat spreader is predetermined shape; according to the heat spreader of the present invention, (i). Due to the side edge of said heat spreader can be protruded and exposed to the side wall of encapsulant (refer to the detailed descriptions in FIG.3), in this manner, a larger chip enables to be accommodated in said heat spreader, furthermore, due to a portion of said heat spreader enables to be exposed to the side wall of encapsulant, in this manner, a new (added) path for heat dissipation of chip being formed, then the heat dissipation for a chip is enhanced, and then the reliability of the chip enables to be enhanced. Accordingly, it is more useful and more reliable for the heat spreader in accordance with the present invention to be used in the electronic industry; in addition said heat spreader may also be comprised of a recessed portion(s) and/or a protruding portion(s), etc. for either enhancing the reliability of an electrical device or being used more convenient as required; (ii). said heat spreader enables to be as close to the chip as possible (refer to FIG. 2; the thickness “T1” of the portion of encapsulant 40 which is between the upper surface 21 of chip 20 and the lower surface 122 of second portion 12 of heat spreader 10 enables to be thinner), then the heat dissipation of the chip 20 is more efficient, and then the reliability of the electrical device enables to be enhanced; and (iii). More surfaces of said heat spreader enables to be encapsulated by an encapsulant. Consequently, the surfaces of said heat spreader contacted with the encapsulant is increased, in this manner, said heat spreader enables to be encapsulated (held) by the encapsulant more securely, then the peeling-off problem(i.e. the heat spreader being separated from the encapsulant) can be avoided, and then the reliability of the electrical device enables to be enhanced;

The mentioned-above and further objects of the present invention will be more adequately appeared from the detailed description, accompanying drawings and appended claims as follow.

### BRIEF DESCRIPTION OF THE DRAWINGS

FIG. 1 is a cross-sectional view showing a preferred embodiment of heat spreader in accordance with the present invention.

FIG. 2 is a cross-sectional view showing a preferred embodiment of electrical device, wherein the heat spreader in accordance with the present invention is used.

FIG. 3 is a cross-sectional view showing a preferred embodiment of electrical device, wherein the heat spreader in accordance with the present invention is used.

FIG. 4 is a cross-sectional view showing a preferred embodiment of electrical device, wherein the heat spreader in accordance with the present invention is used.

FIG. 5 is a cross-sectional view showing a preferred embodiment of electrical device, wherein the heat spreader in accordance with the present invention is used.

FIG. 6 is a cross-sectional view showing a preferred embodiment of electrical device, wherein the heat spreader in accordance with the present invention is used.

FIG. 7 is a cross-sectional view showing a preferred embodiment of electrical device, wherein the heat spreader in accordance with the present invention is used.

FIG. 8 is a cross-sectional view showing a preferred embodiment of electrical device, wherein the heat spreader in accordance with the present invention is used.

FIG. 9 is a top view showing a preferred embodiment of electrical device, wherein the heat spreader in accordance with the present invention is used.

FIG. 10 is a cross-sectional view showing a preferred embodiment of electrical device, wherein the heat spreader in accordance with the present invention is used.

FIG. 11 is a cross-sectional view showing a preferred embodiment of electrical device which is sliced apart from the electrical device shown in FIG. 10, wherein the heat spreader in accordance with the present invention is used.

FIG. 12 is a cross-sectional view showing a preferred embodiment of electrical device, wherein the heat spreader in accordance with the present invention is used.

FIG. 13 shows a cross-sectional view of electrical device according to a prior art.

### DETAILED DESCRIPTION OF PREFERRED EMBODIMENTS

Embodiments of heat spreader in accordance with the present invention will be explained with reference to the drawings as follow:

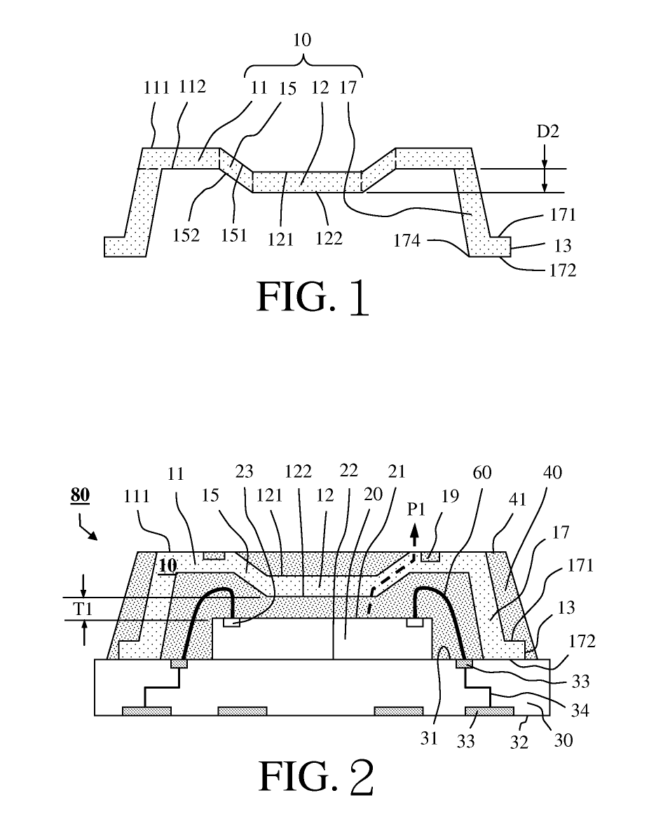

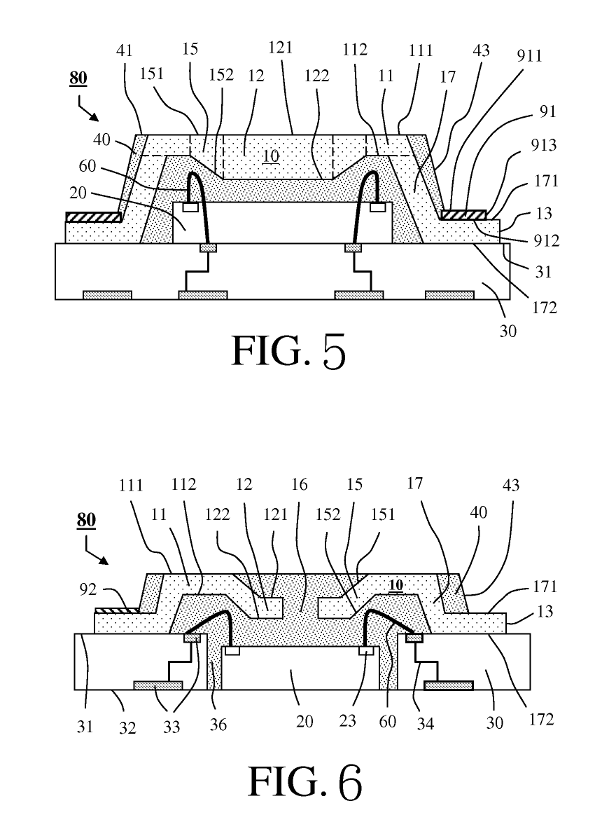

FIG. 1 is a cross sectional view of a preferred embodiment of the heat spreader 10 in accordance with the present invention, said heat spreader 10 consists of the primary characteristics related to the heat spreader in accordance with the present invention, said heat spreader 10 is comprising: a first portion 11 having an upper surface 111 and a corresponding lower surface 112, a second portion 12 having an upper surface 121 and a corresponding lower surface 122 and a connecting portion 15 having an upper surface 151 and a corresponding lower surface 152, said connecting portion 15 is between said first portion 11 and said second portion 12 of heat spreader 10, wherein the first portion 11 and the second portion 12 are not in the same horizontal level, and the heat spreader 10 formed by the first portion 11, second portion 12 and connecting portion 15 is a predetermined shape which is staircase-shaped (i.e. step configuration), furthermore, said heat spreader 10 further comprising a supporting portion(s) 17 and a side edge(s) 13, said supporting portion 17 is connected to the periphery of said first portion 11 for supporting said first, connecting second portions 11, 15, 12; said supporting portion 17 having an upper surface 171 and a corresponding lower surface 172 and an inside edge 174, wherein the side edge 13 of heat spreader 10 is between said upper surface 171 and said lower surface 172 of said supporting portion 17, according to the heat spreader 10 shown in FIG. 1, due to said heat spreader 10 is staircase-shaped, there is a distance “D2” between the first portion 11 and the second portion 12, because of the distance “D2”, it allows said heat spreader 10 to be as close to the chip (refer to the “20” in FIG. 2) as possible; consequently. Not only the heat dissipation of chip 20 is enhanced but the reliability of electrical device is also improved (the detailed description will be explained in FIG. 2 too), in addition, the upper surfaces 111,151,121 or the lower surfaces 112,152,122 of said first, connecting second portions 11, 15, 12 can be coplanar (refer to FIGS. 5 & 7); Moreover, said heat spreader 10 can also further including a plating layer (not shown) which is(are) coated on said heat spreader 10 by means of plating process in order to prevent said heat spreader 10 from rust, scratch etc.

FIGS. 2-12 show embodiments of electrical device in accordance with the present invention, wherein the heat spreaders of electrical device being used by the preferred embodiments of the heat spreader related to this invention.

FIG. 2 shows an electrical device 80, wherein a preferred embodiment of heat spreader 10 in accordance with the present invention is involved therein, basically, the structure of the heat spreader 10 is similar to the structure of the heat spreader (10) shown in FIG. 1, the difference is that said heat spreader 10 shown in FIG. 2 is: there is a recessed portion(s) 19 formed on the upper surface 111 of first portion 11; said electrical device 80 consists of a base 30 serving as a substrate; the heat spreader 10 is mounted on the upper surface 31 of the base 30 by way of its supporting portion 17; a chip 20 accommodating in said heat spreader 10 is mounted on the upper surface 31 of substrate 30 by its lower surface 22; a plurality of conductive means serving as conductive wires 60 electrically connected the bond pads 23 disposed on the upper surface 21 of chip 20 to the conductive terminals 33 formed on the upper surface 31 of substrate 30 respectively, meanwhile a plurality of conductive terminals 33 formed on the lower surface 32 of substrate 30 connect to the conductive terminals 33 formed on the upper surface 31 of substrate 30 through a plurality of via 34 respectively; an encapsulant 40 encapsulates said heat spreader 10, said chip 20, said conductive means 60 and said base 30; wherein said heat spreader 10 is coupled with the upper surface 31 of base 30 through the lower surface 172 of the supporting portion 17 of said heat spreader 10, and wherein the upper surface 111 of first portion 11 of said heat spreader 10 is exposed to the upper surface 41 of encapsulant 40, according to said heat spreader 10 of the present invention, due to Not only both the second potion 12 and the connecting portion 15 of said heat spreader 10 enable to be encapsulated by the encapsulant 40 entirely, but the second portion 12 of said heat spreader 10 enables to be getting as close to the chip 20 as possible, then (i). due to the main path “P1” of heat dissipation of chip 20 is from the chip 20 passing through the portion of encapsulant 40 which is between the second portion 12 of heat spreader 10 and the chip 20, the second portion 12, the connecting portion 15, the first portion 11, then to the atmosphere, wherein because the second portion 12 of said heat spreader 10 enables to be getting closer to the chip 20, in this manner, compared with the thickness “T” involved in the conventional electrical device shown in FIG. 13, the thickness “T1” (shown in FIG. 2) of encapsulant 40 which is between the second portion 12 of heat spreader 10 and the chip 20 enables to becomes thinner, as this result, the heat dissipation of chip 20 enables to be enhanced (i.e. the heat generated by the chip 20 can be transferred to the heat spreader 10 faster), because usually, the heat spreader 10 is made of metal such as copper which is a high thermally-conductive material, wherein the thermal conductivity of heat spreader 10 (e.g. copper, its thermal conductivity is 390 w/m-k) is excellent, however the thermal conductivity of encapsulant (e.g. “GE-100” produced by NITTO DENKO, its thermal conductivity is 3.1 w/m-k) is very poor, in this manner, once the thickness “T1” mentioned above is thinner, then the heat generated by the chip 20 can be transferred to the second portion 12 of the heat spreader 10 more quickly, and then the heat dissipation of the chip 20 is more effective;

(ii). due to the both the lower surface 122 and the upper surface 121 of second potion 12 of said heat spreader 10 are all encapsulated by the encapsulant 40, in this manner, the surfaces of said heat spreader 10 contacted with the encapsulant 40 is increased, then said heat spreader 10 enables to be held by the encapsulant 40 more securely, consequently, the peeling-off problem(i.e. the gap caused by thermal stress and occurred between the lower surface 122 of second portion 12 of said heat spreader 10 and the portion of encapsulant 40 which is contacted with the lower surface 122 of said second portion 12) can be avoided, in this manner, the reliability of the electrical device 80 shown in FIG. 2 is enhanced; In addition, the recessed portion 19 formed on the upper surface 111 of first portion 11 is for preventing the encapsulant 40 from overflowing the molding tool (not shown), while operating the filling process of encapsulant (not shown).

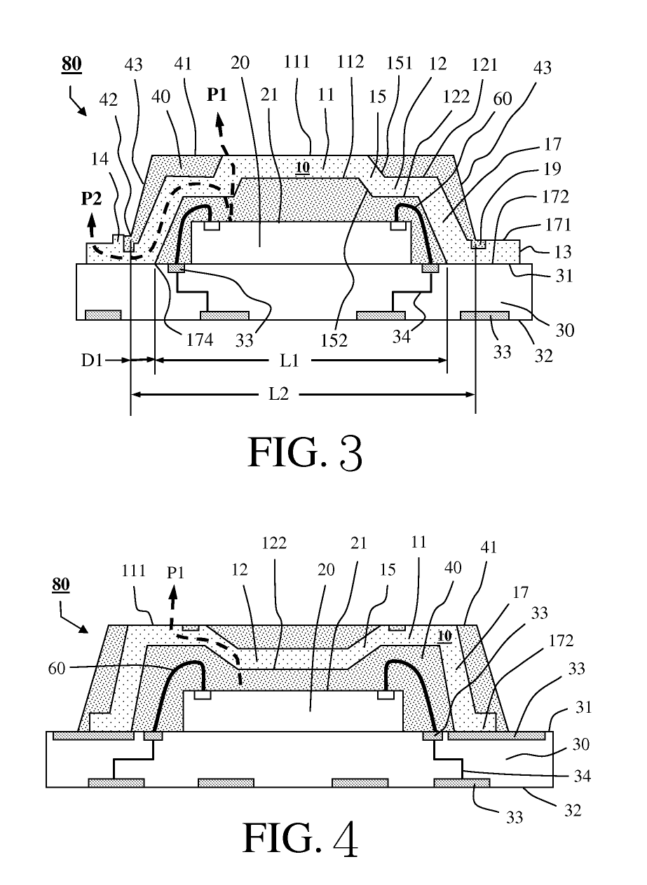

FIG. 3 shows an electrical device 80, wherein a further preferred embodiment of heat spreader 10 in accordance with the present invention is involved therein, said heat spreader 10 having a first portion 11, second portion 12, connecting portion 15, supporting portion 17, protruding portion 14, recessed portion 19 and a side edge 13; said first portion 11, second portion 12, connecting portion 15, supporting portion 17 having an upper surface 111,121,151,171 and a corresponding lower surface 112,122,152,172 respectively, the connecting portion 15 is between the first portion 11 and the second portion 12, wherein the first portion 11 and the second portion 12 are not in the same horizontal level (i.e. the first portion 11, connecting portion 15 and second portion 12 is forming by a step configuration) in order that the lower surface 122 of second portion 12 enables to be as close to the upper surface 21 of chip 20 as possible; Moreover, the side edge 13 of heat spreader 10 being protruded and exposed to the side wall 43 of encapsulant 40, then the upper surface 171 of supporting portion 17 being not encapsulated to the encapsulant 40 (that is to say the upper surface 171 of supporting portion 17 of heat spreader 10 is exposed to the side wall 43 of encapsulant 40 too), in this manner, the distance “D1” between the side edge 42 of encapsulant 40 and the inside edge 174 of supporting portion 17 enables to be shortened (compared with the distance “D” shown in FIG. 13 associated with the descriptions of the distance “D”), and wherein the length “L2” shown in FIG. 3 is equal to the length “L2” shown in FIG. 13, meanwhile, due to the distance “D1” shown in FIG. 3 is shortened, in this manner, said distance “D1” is shorter than the distance “D” shown in FIG. 13, wherein because the length “L2” shown in FIG. 3 is equal to the length “L2” shown in FIG. 13, then the length “L1” shown in FIG. 3 enables to be elongated, and then said length “L1” shown in FIG. 3 is longer than the length “L” shown in FIG. 13, in this manner, a larger chip can be placed in the heat spreader 10 in accordance with the present invention shown in FIG. 3. Furthermore, due to the side edge 13 of heat spreader 10 being protruded and exposed to the side wall 43 of encapsulant 40, the upper surface 171 of supporting portion 17 enables to be exposed to the side wall 43 of encapsulant 40 too, then a new path “P2” for heat dissipation is formed, said new path “P2” allows the heat generated by the chip 20 to be dissipating from the chip 20 passing through the encapsulant 40, the second portion 12, and then to the upper surface 171 of the supporting portion 17 in order to enhance the heat dissipation of chip 20 more effectively, in this manner, the heat generated by chip 20 can be dissipated through both the paths “P1” and “P2”, then the heat dissipation of chip 20 is more effective. By means of the side edge 13 of heat spreader 10 being protruded and exposed to the side wall 43 of encapsulant 40. Not only a larger chip enables to be placed within the heat spreader 10 but a new path “P2” for heat dissipation also enables to be formed, consequently, the restriction for application of said electrical device 80 shown in FIG. 3 is diminished, and the dissipation for the chip 20 can be more effective, and then it is good for the electronic industry; meanwhile, the recessed portion 19 and the protruding portion 14 of heat spreader 10 are for preventing the encapsulant 40 from overflowing, while performing the filling process of encapsulant (not shown).

FIG. 4 shows an electrical device 80 which is similar to the structure of the electrical device (80) shown in FIG. 2, the difference is that the lower surface 172 of supporting portion 17 is also connected to the conductive terminals 33 on the upper surface 31 of base 30, then said heat spreader 10 can either electrically connect to the outside such as a printed circuit board or enhance the heat dissipation of chip 20.

FIG. 5 shows an electrical device 80, wherein a further preferred embodiment of heat spreader 10 in accordance with the present invention is involved therein, basically, the structure of the heat spreader 10 is similar to the structure of the heat spreader (10) shown in FIG. 1, the difference is that said heat spreader 10 shown in FIG. 5 is: the upper surfaces 111,121,151 of first, second, connecting portions 11,12,15 are in the same horizontal level(i.e. the upper surfaces 111,121,151 are coplanar), nevertheless, the lower surfaces 112,122,152 of first, second, connecting portions 11,12,15 are not in the same horizontal level (i.e. the shape formed by the lower surfaces 112,122,152 is staircase-shaped), said heat spreader 10 is coupled with the upper surface 31 of base 30; a buffer 91 having an upper surface 911, a corresponding lower surface 912 and a side edge 913, said buffer 91 mounted on the upper surface 171 of supporting portion 17. By means of said buffer 91, it allows the molding tool (not shown) to mesh with the heat spreader 10 well, in this manner, the molding tool (not shown) can hermetically seal the heat spreader 10 more firmly while said molding tool being coupled with the upper surface 911 of buffer 91, in order that the encapsulant 40 will not be leaking out of said molding tool, while operating the filling process (not shown) of encapsulant, wherein the buffer 91 is made of insulative material such as solder mask etc.; and wherein the upper surfaces 111,121,151 of first, second, connecting portions 11,12,15 of said heat spreader 10, the upper surface 911 of buffer 91 and a portion of the upper surface 171 of supporting portion 17 are all exposed to the encapsulant 40; according to the preferred embodiment of the heat spreader 10 shown in FIG. 5, although the shape of the heat spreader 10 is not the same as the shape of heat spreader shown in FIG. 1, nevertheless, the lower surface 122 of second portion 12 of the heat spreader 10 still enables to be as close to the chip 20 as possible, and a larger chip can be placed within the heat spreader 10 (due to the side edge 13 of heat spreader 10 protruded and exposed to the side wall 43 of encapsulant 40), meanwhile a new path for heat dissipation of chip 20 is also formed.

FIG. 6 shows an electrical device 80, wherein a further preferred embodiment of heat spreader 10 in accordance with the present invention is involved therein, basically, the structure of the heat spreader 10 is similar to the structure of the heat spreader (10) shown in FIG. 1, the difference is that said heat spreader 10 shown in FIG. 6 further includes a through hole 16 in the second portion 12 of said heat spreader 10, meanwhile the base 30 further having a through hole 36 for accommodating the chip 20; and a protective layer 92 formed on the upper surface 171 of supporting portion 17 is made of gold, metallic alloy etc; the chip 20, conductive means 60, heat spreader 10, base 30 and said protective layer 92 are encapsulated by the encapsulant 40, wherein the chip 20 placed in the through hole 36 of base 30 is coupled with said base 30 through the encapsulant 40; In the preferred embodiment of heat spreader 10 shown in FIG. 6, due to there is a through hole in the second portion 12 of said heat spreader 10, thus (i). it allows the encapsulant 40 on the upper surface 121 of second portion 12 and the encapsulant 40 underneath the lower surface 122 of second portion 12 enables to be combined each other(i.e. be unitary), in this manner, the heat spreader 10 can be secured by the encapsulant 40 more firmly, in order to prevent the peeling-off problems (mentioned in FIG. 13) between the surface of second portion 12 and the encapsulant 40 from being occurred; (ii). By means of the through hole 16 of second portion 12, it is convenient for the encapsulant 40 to encapsulate the chip 20 placed in the through hole 36 of base 30, conductive means 60 accommodating in the heat spreader 10 and said heat spreader 10, wherein the through hole 16 may be placed in the suitable place(s) of the heat spreader 10 such as the first portion 11, connecting portion 15 and/or the supporting portion 17 as required; In addition, the protective layer 92 formed on the upper surface 171 of supporting portion 17 is for protecting said upper surface 171 of supporting portion 17 (i.e. while operating the filling process, the encapsulant 40 can flow into the molding tool (not shown) through the protective layer 92 but not touching the upper surface 171 of supporting portion 17) because during the period of filling process, the temperature of encapsulant will be up to 175° C., and the upper surface 171 of supporting portion 17 may be burned (damaged).

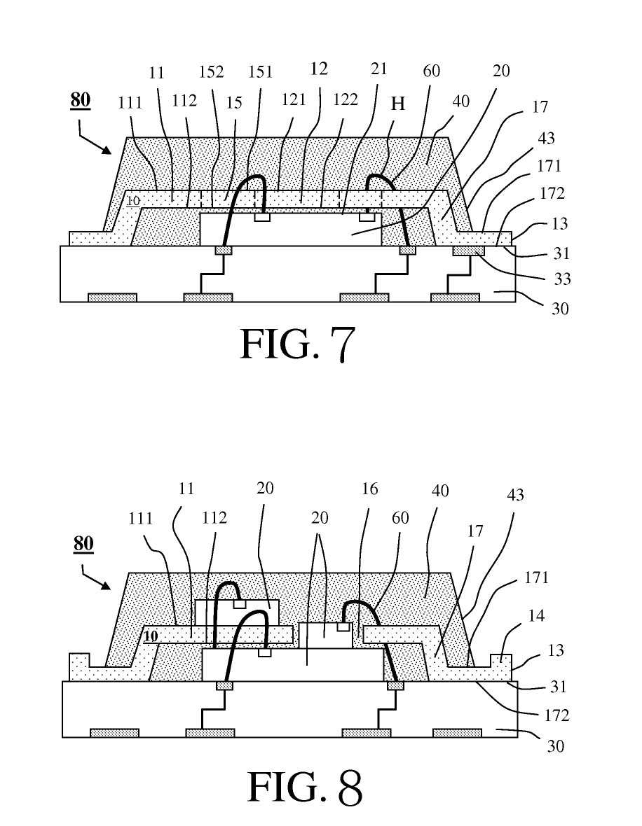

FIG. 7 shows an electrical device 80, wherein the upper surfaces 111,121,151 of first, second, connecting portions 11,12,15 of heat spreader 10 are in the same horizontal level(i.e. the upper surfaces 111,121,151 are coplanar),meanwhile the lower surfaces 112,122,152 of first, second, connecting portions 11,12,15 of heat spreader 10 are coplanar too; according to said preferred embodiment of heat spreader 10 shown in FIG. 7, the lower surfaces 112,122,152 of first, second, connecting portions 11,12,15 of heat spreader 10 are all below the highest height “H” of conductive mean(wire) 60 in order that there are more areas of said heat spreader 10 getting closer to the chip 20, then the heat dissipation of chip 20 enables to be enhanced more efficiently, moreover, due to it is possible for the heat spreader 10 to be very close to the chip 20, and due to the lower surface 172 of supporting portion 17 also connected to one(s) of the conductive terminals 33 formed on the upper surface 31 of base 30, then said heat spreader 10 can be used for preventing the chip 20 from electromagnetic interference too; In addition, the heat generated by chip 20 is dissipated to the outside by the portion of upper surface 171 of supporting portion 17 which is exposed to the encapsulant 40.

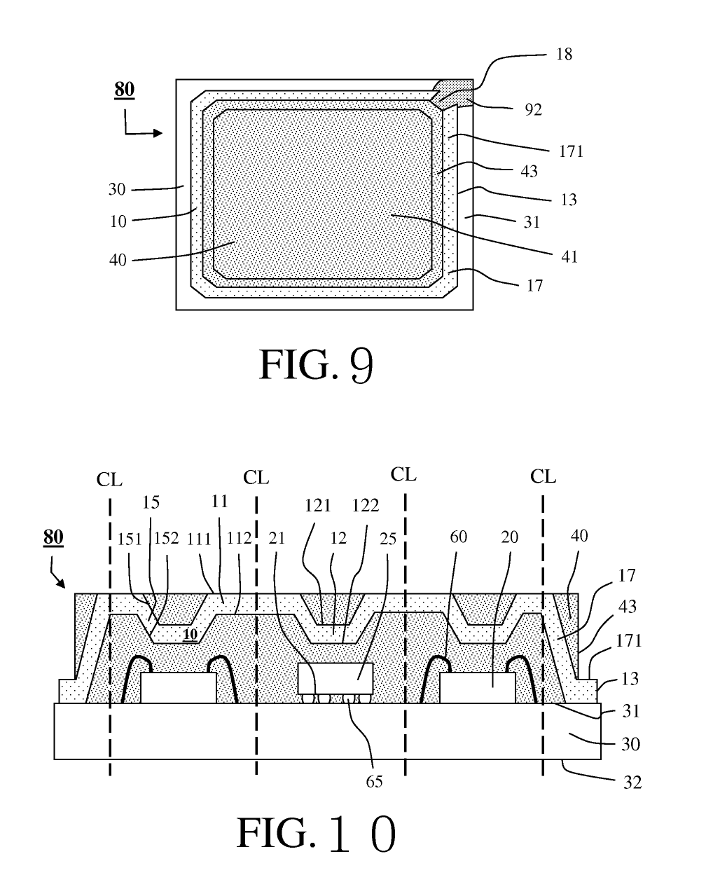

FIG. 8 shows an electrical device 80, wherein the structure of heat spreader 10 shown in FIG. 8 in similar to the structure of heat spreader (10) shown in FIG. 7, the difference is that the heat spreader 10 further includes a through hole 16 which is in the first portion 11 of said heat spreader 10 and a protruding portion 14 formed on the upper surface 171 of supporting portion 17; according to the preferred embodiment of heat spreader 10, due to said heat spreader 10 having a through hole 16, then it allows the chip 20 on the another chip 20 which is coupled with the upper surface 31 of base 30 to be stacked on said another chip 20 and be placed in the through hole 16, meanwhile the other chip 20 enables to be situated on the upper surface 111 of first portion 11 too; consequently. By means of increasing the amount of chips 20, the electrical device 80 becomes more powerful; In addition. By means of the protruding portion 14, there are more surfaces of said heat spreader 10 exposed to the encapsulant 40 for enhancing the heat dissipation of electrical device 80. Furthermore, the electrical device 80 herein is serving as a module.

FIG. 9 is a top view showing a structure of electrical device 80 which is similar to the structure of electrical device (80) shown in FIG. 7, the difference is that there is a protective layer 92 formed on the upper surface 31 of base 30; the heat spreader 10 having an opening 18 which is corresponding to the protective layer 92; and due to the opening 18, it allows the encapsulant 40 to encapsulate the chip and the conductive means(wires) accommodated in the heat spreader 10 through the opening 18 conveniently, while operating the filling process of encapsulation; in this manner, it is flexible and convenient to perform the process of encapsulation(i.e. the encapsulation for the chip and the conductive means(wires) accommodated in the heat spreader 10 can be operated by either the through hole (16) shown in FIG. 6 or the opening 18 shown in FIG. 9).

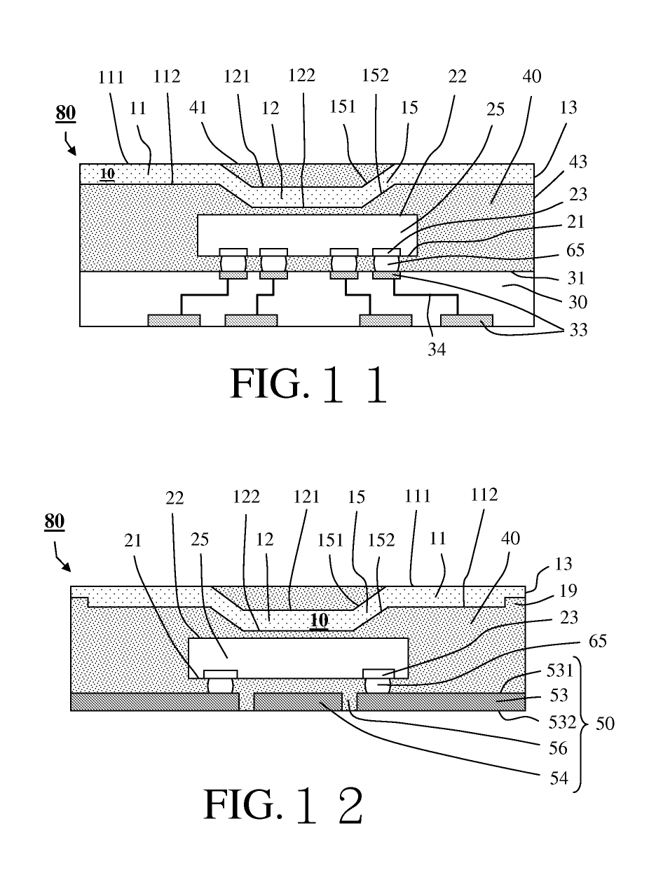

FIG. 10 shows an electrical device 80, wherein a further preferred embodiment of heat spreader 10 in accordance with the present invention is involved therein, basically, the structure of the heat spreader 10 is similar to the structure of the heat spreader (10) shown in FIG. 1, the difference is that said heat spreader 10 shown in FIG. 10 having a plurality of first portions 11, second portions 12 and connecting portions 15 which are connected to each other; according to said electrical device 80, a plurality of chips 20,25 mounted on the upper surface 31 of base 30 respectively, wherein the upper surface 21 of chip 25 is electrically connected to the upper surface 31 of base 30 and mounted thereon through a plurality of conductive means serving as conductive bumps 65 and the chips 20 electrically connected to the upper surface 31 of base 30 through a plurality of conductive means(wires) 60, said chips 20,25 are all accommodated in the heat spreader 10, wherein each lower surface 122 of second portion 12 is above and corresponding to each chip(20,25), in this manner, each lower surface 122 of second portion 12 enables to be as close to each corresponding chip(20,25) as possible; said heat spreader 10, chips 20,25, conductive means 60,65 and said base 30 are encapsulated by the encapsulant 40, wherein each upper surface 111 of first portion 11 of heat spreader 10 is exposed to the encapsulant 40; In the preferred embodiment of electrical device 80 shown in FIG. 10, wherein said electrical device 80 can also be separated into a plurality of individual electrical devices(refer to FIG. 11) along the cutting line “CL”; accordingly, it is reliable and flexible for the heat spreader 10 in accordance with the present invention to be used in the electrical device 80.

FIG. 11 shows an electrical device 80 which is sliced apart from the electrical device (80) shown in FIG. 10, comprising: a base 30 serving as a substrate which is the same as the base (30) shown in FIG. 2 substantially; a chip 25 having an upper surface 21, a corresponding lower surface 22, wherein said chip 25 having a plurality of bond pads 23 disposed on the upper surface 21 of said chip 25 is electrically connected to the upper surface 31 of base 30 and mounted thereon through a plurality of conductive means(bumps) 65; a heat spreader 10 having a first portion 11, second portion 12, connecting portion 15 and a side edge 13, wherein each first, second, connecting portion 11,12,15 having an upper surface 111,121,151 and a corresponding lower surface 112, 122,152 respectively, said connecting portion 15 is between said first portion 11 and said second portion 12, wherein the shape of said heat spreader 10 is staircase-shaped, in this manner, the lower surface 122 of second portion 12 enables to be as close to the chip 25 as possible, and wherein said heat spreader 10 is above and corresponding to the chip 25; an encapsulant 40 encapsulates said heat spreader 10, chip 25, conductive means 65 and said base 30, wherein the upper surface 111 of first portion 11 associated with the side edge 13 of heat spreader 10 are exposed to the encapsulant 40 exclusively; In the preferred embodiment of heat spreader 10 shown in FIG. 11, wherein although said heat spreader 10 is neither comprised of any supporting portion(refer to the “17” shown in FIG. 10) nor contacted with the base 30, nevertheless, the lower surface 112 of second portion 12 of heat spreader 10 still enables to be closer to the chip 25 in order to enhance the heat dissipation of chip 25, furthermore. Due to both the upper surface 121of second portion 12 and the upper surface 151of connecting portions 15 are all encapsulated by the encapsulant 40(i.e. the surfaces of heat spreader 10 contacted with the encapsulant 40 is increased), in this manner, said heat spreader 10 enables to be secured by the encapsulant 40 more firmly, then the reliability of said electrical device 80 cane be enhanced, moreover, due to the supporting portion of heat spreader 10 is omitted, then a bigger chip can be involved in the electrical device 80, and then the limitation for using said heat spreader 10 is decreased; In addition, an adhesive mean formed by highly conductive heat material such as conductive epoxy, conductive film or a highly conductive glue etc. may be positioned between the heat spreader 10 and the chip 25 in order that it is more effective for the heat generated by the chip 25 to be transferring to the heat spreader 10; furthermore, the heat spreader 10 may also be including a through hole(refer to the “16” in FIG. 6) for operating the encapsulation process easily and being fixed the heat spreader 10 by encapsulant firmly.

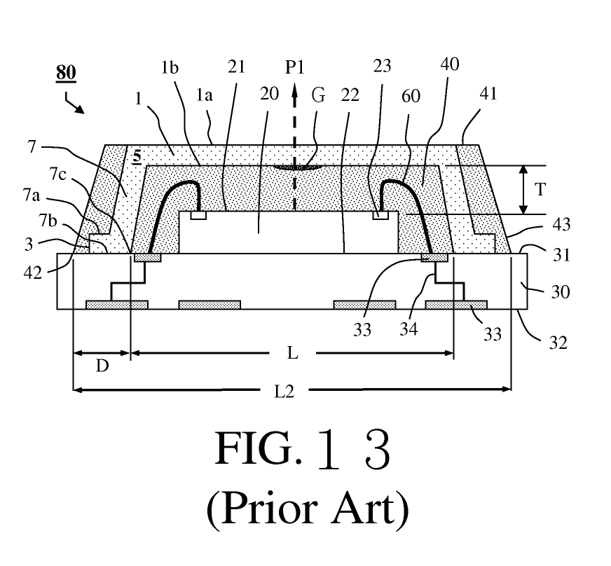

FIG. 12 shows the structure of electrical device 80 is similar to the structure of electrical device (80) shown in FIG. 11, the difference is that the base 50 shown in FIG. 12 herein is serving as a lead frame 50 having a plurality of leads 53 and a die pad 54 which is placed within the through hole 56 of said lead frame 50, each lead 53 having an upper surface 531 and a corresponding lower surface 532, said lead 53 serving as a conductive terminal is for electrical connection, and the lead frame 50 can be made of conductive materials such as copper or metallic alloy etc.; the chip 25 coupled with the leads 53 of the lead frame 50 and electrically connected to said lead frame 50 through a plurality of conductive means(bumps) 65; the heat spreader 10 further including a recessed portion 19 which is formed on the side edge 13 of said heat spreader 10; and the chip 25, heat spreader 10, conductive means 65 and the base 50 are all encapsulated by the encapsulant 40, wherein the upper surface 111 of first portion 11, side edge 13 of heat spreader 10 and the lower surfaces 532 of lead 53 of lead frame 50 are exposed to the encapsulant 40; In the preferred embodiment of heat spreader 10 shown in FIG. 12, due to the recessed portion 19, the thickness of side edge 13 of heat spreader 10 can become thinner, then it is easier to saw the electrical device 80 while operating the sawing process(refer to the “CL” in FIG. 10), and the wear of the sawing tool(not shown) can be reduced, meanwhile the efficiency of sawing can be increased too.

In accordance with the foregoing descriptions accompanying drawings, this invention has been described in terms of several preferred embodiments, various alternations and modifications can be made to become apparent to those skilled in the art; For examples, as shown in FIG. 1, wherein the heat spreader 10 may be made of steel, aluminum, metallic alloy and/or highly conductive heat material etc; as shown in FIGS. 2˜10, wherein the chip can be employed as a semiconductor die, L.E.D.(Light Emitting Diode) chip or transistor, in addition, either the lower surface 172 of supporting portion 17 of heat spreader 10 or the chip 20 may be coupled with the base (substrate 30, lead frame 50) through an adhesive mean(s) such as glue, epoxy, tape, encapsulant or the like, wherein said adhesive mean may be made of conductive materials or non-conductive materials; as shown in FIGS. 2˜6 & 10˜12, wherein the upper surface(s) of the heat spreader 10 exposed to the encapsulant 40 can also be encapsulated by the encapsulant as required, and the chip 20 shown in FIG. 2 can be mounted on said base 30 through an adhesive mean such as epoxy, etc.; as shown in FIG. 3, wherein both the recessed portion 19 and the protruding portion 14 may be placed in the other suitable place(s) of the heat spreader 10 such as the first portion 11 and/or the connecting portion 15 as required; as shown in FIGS. 3 & 11, wherein the chip 20 shown in FIG. 3 and the chip 25 shown in FIG. 11 are interchangeable, in addition, as shown in FIG. 3, wherein the first portion 11 and the second portion 12 of said heat spreader 10 can be interchangeable too; as shown in FIG. 5, wherein the buffer 91 may be situated on the first, portion 11, the connecting portion 15 and/or the second portion 12 as required; as shown in FIG. 6, wherein the heat spreader 10 can also be sliced through the through hole 16, then there will be two heat spreaders (10) which are corresponding to each other and mounted on the base 30, in addition, said electrical device 80 shown in FIG. 6 can just includes a sliced heat spreader (10) as required; as shown in FIG. 10, wherein a plurality of heat spreader 10 may be involved in the electrical device as required. In addition, the upper surface 151 of connecting portion 15 and/or the upper surface 121 of second portion 12 of heat spreader 10 can also be exposed to the encapsulant 40(i.e. the upper surface 151 of connecting portion 15 and/or the upper surface 121 of second portion 12 of heat spreader 10 can be not encapsulated by the encapsulant 40) as required; Accordingly, it is to be understood that the scope of the invention is not limited to the disclosed embodiments but is defined by the appended claims.

What is claimed is:

1. A heat spreader for being coupled with a base, a chip accommodated in said heat spreader and coupled with said base, said chip electrically connected to said base through at least a conductive mean, an encapsulant having at least an upper surface and a side wall, said encapsulant encapsulated said heat spreader, said chip, said conductive mean and said base, and a portion of said heat spreader protruded and exposed to said side wall of encapsulant, comprising:
at least a first portion, a second portion, a connecting portion, a supporting portion and a side edge;
said connecting portion is between said first portion and said second portion;
said supporting portion being connected to the periphery of said first portion for supporting said first portion, said connecting portion and said second portion, said supporting portion having at least an upper surface and a lower surface, wherein said side edge of said heat spreader is between said upper surface of said supporting portion and said lower surface of said supporting portion, said lower surface of supporting portion is coupled with said base; and
wherein said side edge of heat spreader being protruded and exposed to the side wall of said encapsulant, in this manner, at least a portion of said upper surface of said supporting portion being protruded and exposed to said side wall of said encapsulant.

2. The heat spreader of claim 1, wherein said heat spreader is staircase-shaped, and wherein said first portion of heat spreader, said second portion of heat spreader and said connecting portion of heat spreader being not coplanar.

3. The heat spreader of claim 1, wherein said first portion, said second portion and said connecting portion being coplanar.

4. The heat spreader of claim 1, wherein said heat spreader further including at least a plating layer.

5. An electrical device, comprising:
at least a base;
at least a chip, said chip coupled with said base, wherein said chip electrically connected to said base through at least a conductive mean;
at least a heat spreader including at least a first portion, a second portion, a connecting portion, a supporting portion and a side edge, said connecting portion is between said first portion and said second portion, said supporting portion being connected to the periphery of said first portion for supporting said first portion, said connecting portion and said second portion, said supporting portion having at least an upper surface and a lower surface, and said side edge of said heat spreader is between said upper surface of said supporting portion and said lower surface of said supporting portion, said lower surface of supporting portion is coupled with said base, both said chip and said conductive mean accommodated in said heat spreader;
an encapsulant having at least an upper surface and a side wall, said encapsulant encapsulated said chip, said conductive mean, said base and said heat spreader, and
wherein said side edge of heat spreader being protruded and exposed to the side wall of said encapsulant, in this manner, at least a portion of said upper surface of said supporting portion being protruded and exposed to said side wall of said encapsulant.

6. The electrical device of claim 5, wherein said heat spreader having at least a through hole.

7. The electrical device of claim 5, wherein said heat spreader having at least an opening.

8. The electrical device of claim 5, wherein said heat spreader further including at least a recessed portion.

9. The electrical device of claim 5, wherein said heat spreader further including at least a protruding portion.

10. The electrical device of claim 5, further including at least a buffer, wherein said buffer is upon said heat spreader, and wherein said buffer is made of insulator.

11. The electrical device of claim 5, further including at least a protective layer, wherein said protective layer is upon said heat spreader, and wherein said protective layer is made of metallic material.

12. The electrical device of claim 5, wherein said heat spreader is staircase-shaped, and wherein said first portion of heat spreader, said second portion of heat spreader and said connecting portion of heat spreader being not coplanar.

13. The electrical device of claim 5, wherein said first portion of heat spreader, said second portion of heat spreader and said connecting portion of heat spreader being coplanar.

14. The electrical device of claim 5, wherein the upper surface of first portion of heat spreader, the upper surface of second portion of heat spreader and the upper surface of connecting portion of heat spreader being encapsulated by said encapsulant.

15. The electrical device of claim 5, wherein at least a portion of said first portion of heat spreader being exposed to said encapsulant.

16. The electrical device of claim 5, wherein at least a portion of said second portion of heat spreader being exposed to said encapsulant.

17. The electrical device of claim 5, wherein said conductive mean is selectively serving as a conductive wire or a conductive bump.

18. The electrical device of claim 5, wherein said base is selectively serving as a substrate or a lead frame.

19. The electrical device of claim 5, wherein said heat spreader further including at least a plating layer.
